(19) United States
(12) Patent Application Publication
(10) Pub. No.: US 2025/0279391 A1
(43) Pub. Date: Sep. 4, 2025

(54) SEMICONDUCTOR PACKAGE

(71) Applicant: Samsung Electronics Co., Ltd., Suwon-si (KR)

(72) Inventors: Jing Cheng LIN, Suwon-si (KR); Kwangbae Kim, Suwon-si (KR)

(73) Assignee: Samsung Electronics Co., Ltd., Suwon-si (KR)

(21) Appl. No.: 18/818,214

(22) Filed: Aug. 28, 2024

(30) Foreign Application Priority Data
Feb. 29, 2024 (KR) 10-2024-0030000

(51) Int. Cl. H01L 23/00; H01L 25/065

(52) U.S. Cl. CPC H01L 24/80; H01L 24/08; H01L 25/0657; H01L 2224/08146; H01L 2224/80075; H01L 2224/80365; H01L 2224/80895; H01L 2224/80896; H01L 2225/06541; H01L 2225/06565

(57) ABSTRACT

A semiconductor package includes: a plurality of semiconductor chips; a plurality of bonding pads between two of the plurality of semiconductor chips; a bonding insulating layer surrounding the plurality of bonding pads between the two of the plurality of semiconductor chips; and a void controller between the plurality of bonding pads, wherein the plurality of bonding pads are directly connected to the two of the plurality of semiconductor chips, wherein the bonding insulating layer is directly connected to the two of the plurality of semiconductor chips, wherein the void controller is a cavity defined by the bonding insulating layer, one of the plurality of semiconductor chips, and the bonding insulating layer, or the one of the plurality of semiconductor chips and the bonding insulating layer, and wherein the void controller is filled with a gas.

### CROSS-REFERENCE TO RELATED APPLICATION

This application claims priority under 35 USC § 119 to Korean Patent Application No. 10-2024-0030000, filed on Feb. 29, 2024, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package in which two dies are directly stacked through wafer-to-wafer bonding.

### 2. Brief Description of Related Art

In accordance with the rapid development of the electronics industry and user demand, electronic devices have become smaller and lighter. As electronic devices have become smaller and lighter, semiconductor packages used therein have also become smaller and lighter and have been required to be highly integrated and have high speed. In accordance with the demand for highly integrated and high-speed semiconductor packages, semiconductor packages including stacked semiconductor chips have been developed.

### SUMMARY

Embodiments of the present disclosure provide a semiconductor package with improved reliability using stacked semiconductor chips.

However, problems solved by embodiments of the present disclosure are not limited to the problems mentioned above, and other problems that are solved by embodiments of the present disclosure may be clearly understood by those skilled in the art from the description below.

According to embodiments of the present disclosure, a semiconductor package is provided and includes: a plurality of semiconductor chips; a plurality of bonding pads between two of the plurality of semiconductor chips; a bonding insulating layer surrounding the plurality of bonding pads between the two of the plurality of semiconductor chips; and a void controller between the plurality of bonding pads, wherein the plurality of bonding pads are directly connected to the two of the plurality of semiconductor chips, wherein the bonding insulating layer is directly connected to the two of the plurality of semiconductor chips, wherein the void controller is a cavity defined by the bonding insulating layer, one of the plurality of semiconductor chips, and the bonding insulating layer, or the one of the plurality of semiconductor chips and the bonding insulating layer, and wherein the void controller is filled with a gas.

According to embodiments of the present disclosure, a semiconductor package is provided and includes a first semiconductor chip including: a first semiconductor substrate including an active surface and an inactive surface opposite to each other; and first through-electrodes passing through the first semiconductor substrate; and second semiconductor chips, each including: a second semiconductor substrate including an active surface and an inactive surface opposite to each other; and second through-electrodes passing through the second semiconductor substrate, wherein the second semiconductor chips are stacked on the first semiconductor chip so that the active surface of the second semiconductor substrate faces towards the inactive surface of the first semiconductor substrate, wherein the semiconductor package further includes: first bonding pads between the first semiconductor chip and a lowermost second semiconductor chip among the second semiconductor chips, the first bonding pads electrically connecting the first through-electrodes and the second through-electrodes of the lowermost second semiconductor chip; second bonding pads between a pair of the second semiconductor chips, among the second semiconductor chips, that are adjacent to each other, the second bonding pads electrically connecting the second through-electrodes of one second semiconductor chip among the pair of the second semiconductor chips to another second semiconductor chip among the pair of the second semiconductor chips; a first bonding insulating layer surrounding the first bonding pads, and between the first semiconductor chip and the lowermost second semiconductor chip; a second bonding insulating layer surrounding the second bonding pads, and between the pair of the second semiconductor chips; and a first void controller between the first bonding pads or between the second bonding pads, and wherein the first void controller includes a cavity filled with a gas.

According to embodiments of the present disclosure, a semiconductor package is provided and include a first semiconductor chip including: a first semiconductor substrate including an active surface and an inactive surface opposite to each other; and first through-electrodes passing through the first semiconductor substrate; and second semiconductor chips, each including: a second semiconductor substrate including an active surface and an inactive surface opposite to each other; and second through-electrodes passing through the second semiconductor substrate, wherein the second semiconductor chips are stacked on the first semiconductor chip so that the active surface of the second semiconductor substrate faces towards the inactive surface of the first semiconductor substrate, wherein the semiconductor package further includes: first bonding pads between the first semiconductor chip and a lowermost second semiconductor chip among the second semiconductor chips, the first bonding pads electrically connecting the first through-electrodes and the second through-electrodes of the lowermost second semiconductor chip; second bonding pads between a pair of the second semiconductor chips, among the second semiconductor chips, that are adjacent to each other, the second bonding pads electrically connecting the second through-electrodes of one second semiconductor chip among the pair of the second semiconductor chips to another second semiconductor chip among the pair of the second semiconductor chips; a first bonding insulating layer surrounding the first bonding pads, and between the first semiconductor chip and the lowermost second semiconductor chip; a second bonding insulating layer surrounding the second bonding pads, and between the pair of the second semiconductor chips; and a first void controller that is between and separated from the first bonding pads, wherein the first void controller includes a cavity that is defined by at least one from among the first bonding insulating layer, the first semiconductor chip, and the lowermost second semiconductor chip.

### BRIEF DESCRIPTION OF DRAWINGS

Embodiments will be more clearly understood from the following detailed description taken in conjunction with the accompanying drawings in which:

FIG. 1 is a schematic cross-sectional view illustrating a bonding structure according to an embodiment;

FIG. 2 is a schematic plan view illustrating a bonding structure according to an embodiment;

FIG. 3A is a schematic plan view illustrating a bonding structure according to an embodiment;

FIG. 3B is a schematic plan view illustrating a bonding structure according to an embodiment;

FIG. 3C is a schematic plan view illustrating a bonding structure according to an embodiment;

FIG. 3D is a schematic plan view illustrating a bonding structure according to an embodiment;

FIG. 4 is a schematic cross-sectional view illustrating a bonding structure according to an embodiment;

FIG. 5 is a schematic cross-sectional view illustrating a bonding structure according to an embodiment;

FIG. 6 is a cross-sectional view illustrating a semiconductor package according to an embodiment; and

FIGS. 7, 8, 9, 10, and 11 are cross-sectional views illustrating a sequential process of a method of manufacturing a semiconductor package according to an embodiment.

### DETAILED DESCRIPTION

The advantages and features of embodiments (including methods) of the present disclosure will be apparent from the following non-limiting example embodiments that will be described in more detail with reference to the accompanying drawings. However, embodiments of the present disclosure are not limited to the example embodiments described below, and may be embodied in various forms. The description of the example embodiments is provided so that the disclosure of the present disclosure is complete and fully conveys the scope of the present disclosure to those skilled in the art. In the drawings, relative sizes of layers and regions may be exaggeratedly illustrated for clarity.

When an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Like reference numerals refer to like elements throughout the specification. As used herein, the term “and/or” includes any and all combinations of one or more of the associated listed items.

It will be understood that when an element or a layer is referred to as being “on” or “above” another element or layer, it can be directly on or above the other element or layer or intervening elements or layers may be present. In contrast, when an element is referred to as being “directly on” or “directly above,” there are no intervening elements or layers.

Spatially relative terms, such as “beneath,” “below,” “lower,” “above,” “upper” and the like, may be used herein for ease of description to describe the relationship of one element or feature to another element(s) or feature(s) and may be construed to encompass different orientations of a device in use or operation in addition to the orientation depicted in the figures. For example, if the device in the drawing is turned over, an element located below another element or feature may then be located above the other element or feature. Accordingly, the term “lower” may include both upward and downward directions. The device may be rotated in different directions (e.g., rotated 90 degrees or any other direction) and the spatially relative descriptors used herein may be interpreted accordingly.

Although “first,” “second,” etc., are used to describe various elements, components and/or sections, it is understood that these elements, components and/or sections are not limited by these terms. These terms are merely used to distinguish one element, component, or section from other elements, components, or sections. Therefore, the first element, first component, or first section mentioned below may also be a second element, second component, or second section within the technical spirit of the inventive concept.

The terminology used herein is for describing example embodiments and is not intended to limit the present disclosure. As used herein, singular forms also include plural forms, unless specifically stated otherwise in the context. As used herein, the terms “comprises” (or “includes”) and/or “comprising” (or “including”) when used in this specification specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used in this specification have the same meaning as commonly understood by those skilled in the art to which the present disclosure pertains. In addition, terms, such as those defined in commonly used dictionaries, should not be interpreted ideally or excessively unless clearly specifically defined.

Hereinafter, non-limiting example embodiments of the present disclosure are described in detail with reference to the accompanying drawings. The same reference numerals are used for the same components in the drawings, and redundant descriptions thereof may be omitted.

In this specification, a horizontal direction may include a first horizontal direction (e.g., the X direction) and a second horizontal direction (e.g., the Y direction) that intersect each other. A direction intersecting the first horizontal direction (e.g., the X direction) and the second horizontal direction (e.g., the Y direction) may be referred to as a vertical direction (e.g., the Z direction). In this specification, a vertical level may be referred to as a height level in the vertical direction (e.g., the Z direction) of any component.

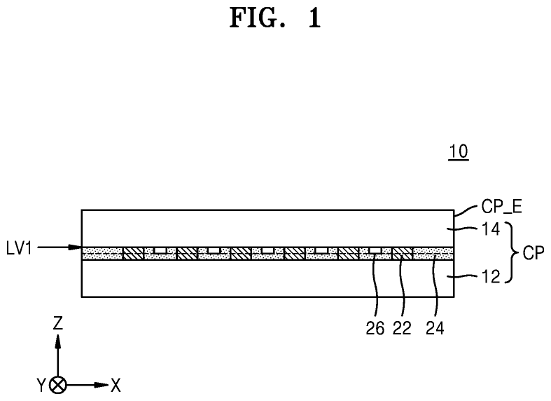

FIG. 1 is a schematic cross-sectional view illustrating a bonding structure 10 according to an embodiment.

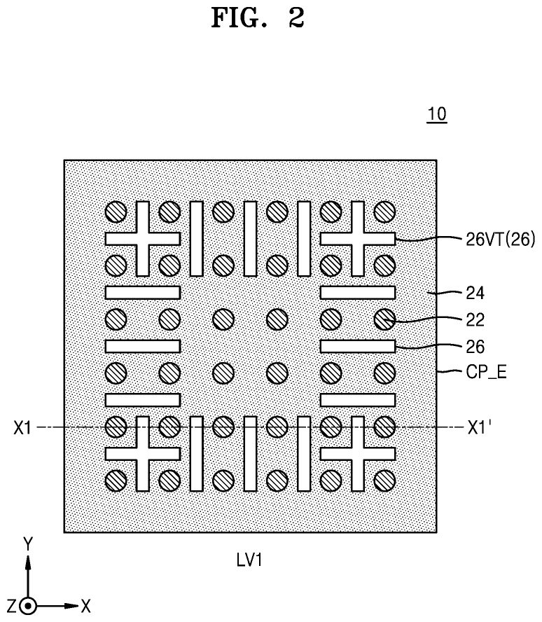

FIG. 2 is a schematic plan view illustrating the bonding structure 10 according to an embodiment.

FIG. 1 may correspond to a cross-section along line X1-X1′ in FIG. 2.

FIG. 2 may be a plan view at a first level LV1 in FIG. 1.

Referring to FIGS. 1 and 2, the bonding structure 10 may include a plurality of semiconductor chips CP including a lower semiconductor chip 12 and an upper semiconductor chip 14, a plurality of bonding pads 22 located between the semiconductor chips CP to connect the semiconductor chips CP, a bonding insulating layer 24 located between the semiconductor chips CP to surround the bonding pads 22, and a plurality of void controllers 26.

The semiconductor chips CP may be memory semiconductor chips. In some embodiments, the semiconductor chips CP may be different types of memory semiconductor chips from each other. In an embodiment, one of the semiconductor chips CP may include a serial-parallel conversion circuit and may be a buffer chip for controlling the other semiconductor chips CP. Here, the other semiconductor chips CP may be memory chips including memory cells. In other embodiments, the semiconductor chips CP may be the same type of memory semiconductor chips as each other. In an embodiment the semiconductor chips CP may be memory chips including memory cells.

Each of the semiconductor chips CP is electrically connected through the bonding pads 22 to exchange signals and provide power and ground. The bonding pads 22 may be located between the semiconductor chips CP.

The bonding pads 22 may be arranged to be apart in the first horizontal direction (e.g., the X direction) and the second horizontal direction (e.g., the Y direction). The bonding pads 22 may constitute at least one row and at least one column including the bonding pads 22. For example, the bonding pads 22 may include a plurality of first bonding pad groups arranged to be apart in a first horizontal direction (e.g., the X direction), and the first bonding pad groups may include the bonding pads 22 arranged to be apart in the second horizontal direction (e.g., the Y direction). In addition, the bonding pads 22 may include a plurality of second bonding pad groups arranged to be apart in the second horizontal direction (e.g., the Y direction), and the second bonding pad groups may include the bonding pads 22 arranged to be apart in the first horizontal direction (e.g., the X direction). The first bonding pad group may form at least one row of the bonding pads 22, and the second bonding pad group may form at least one column of the bonding pads 22. The bonding pads 22 may have a circular layout as shown in FIG. 2, but this is only an example and the bonding pads 22 may have various shapes in the circuit layout. According to embodiments, the shapes may be shapes of bonding pads (e.g., bonding pads 22) in a plan view.

In some embodiments, the bonding pads 22 may be formed through diffusion bonding of forming conductive material layers on surfaces of the semiconductor chips CP, respectively, expanding the conductive material layers by heat to contact each other, and then diffusing metal atoms in the conductive material layers so that the conductive material layers are integrated with each other.

The bonding pads 22 may be surrounded planarly by the bonding insulating layer 24. The bonding insulating layer 24 may be located between the semiconductor chips CP and surround each of the bonding pads 22.

In some embodiments, the bonding insulating layer 24 may be formed through diffusion bonding of forming insulating material layers on surfaces of the semiconductor chips CP, respectively, expanding the insulating material layers by heat to contact each other, and then diffusing metal atoms in the insulating material layers so that the insulating material layers are integrated with each other.

In some embodiments, the bonding pads 22 may include a material capable of diffusion bonding, such as Cu, Al, or W. In some embodiments, the bonding insulating layer 24 may include any one from among SiO, SiN, SiCN, SiCO, and a polymer material. The polymer material may include benzocyclobutene (BCB), polyimide (PI), polybenzoxazole (PBO), silicone, acrylate, or epoxy. For example, the bonding insulating layer 24 may include silicon oxide.

The bonding structure 10 may include the void controllers 26 located between the semiconductor chips CP. The void controllers 26 may have various shapes, for example, a slit shape, a groove shape, or a recess shape. The void controllers 26 may include any cavities filled with an inert gas or gaseous material (including, but not limited to, air).

The void controllers 26 may be located between a pair of neighboring ones of the bonding pads 22. The void controller 26 may be spaced apart from the bonding pads 22 with a portion of the bonding insulating layer 24 therebetween.

The void controllers 26 may be defined by any one of the semiconductor chips CP and the bonding insulating layer 24 and may include a cavity closed by one of the semiconductor chips CP and the bonding insulating layer 24. In an embodiment, as shown in FIG. 1, the void controllers 26 may be defined by the upper semiconductor chip 14 and the bonding insulating layer 24 and may include a cavity closed by the upper semiconductor chip 14 and the bonding insulating layer 24. In another embodiment, the void controllers 26 may be defined by the lower semiconductor chip 12 and the bonding insulating layer 24 and may include a cavity closed by the lower semiconductor chip 12 and the bonding insulating layer 24.

In some embodiments, the void controllers 26 may be located between one of the semiconductor chips CP and the bonding insulating layer 24. In an embodiment, the void controllers 26 may be located between the upper semiconductor chip 14 and the bonding insulating layer 24. In another embodiment, the void controllers 26 may be located between the lower semiconductor chip 12 and the bonding insulating layer 24.

A vertical length of the void controllers 26 in the vertical direction (e.g., the Z direction) is not limited to half a height of the bonding insulating layer 24 in the vertical direction (e.g., the Z direction) as shown and may vary. For example, the vertical length of the void controllers 26 in the vertical direction (e.g., the Z direction) may be less than half the height of the bonding insulating layer 24 in the vertical direction (e.g., the Z direction).

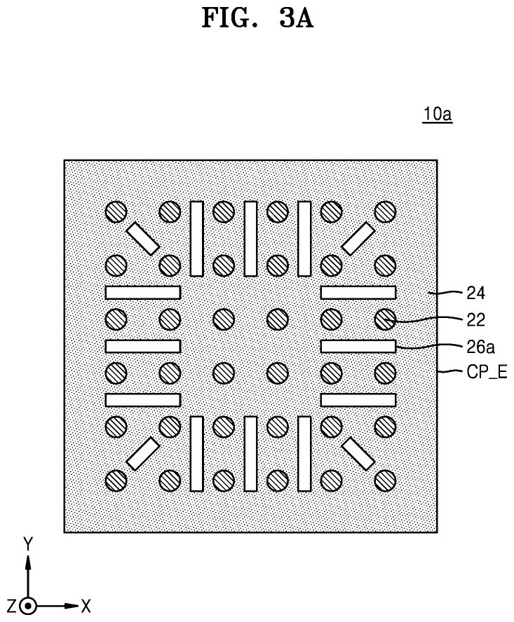

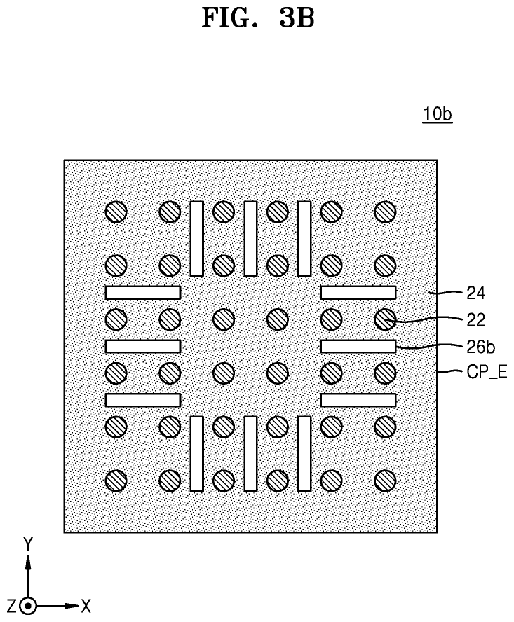

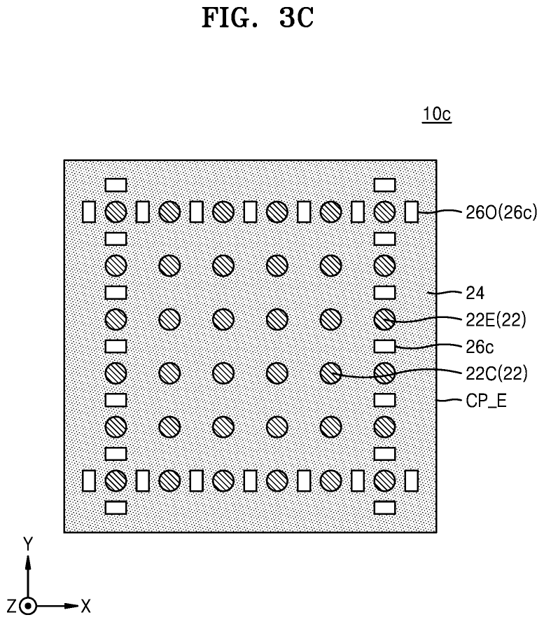

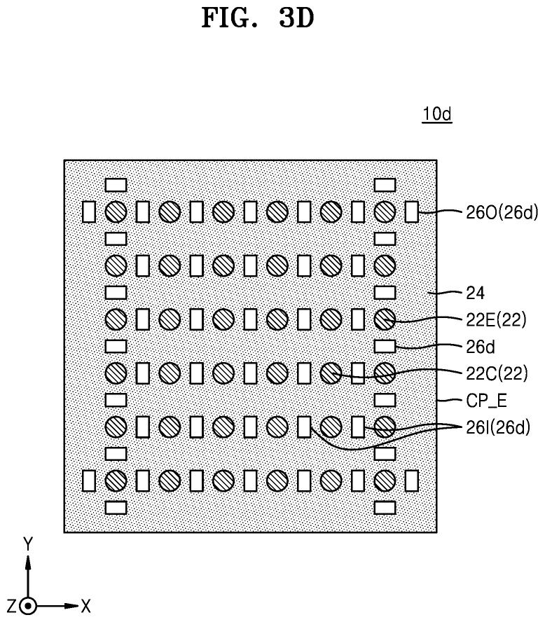

As shown in FIG. 2, the void controllers 26 may have a line shape extending in one direction, a line shape extending in another direction intersecting the one direction, and/or a cross shape. For example, the void controllers 26 may include a line shape extending in the first horizontal direction (e.g., the X direction), a line shape extending in the second horizontal direction (e.g., the Y direction), and/or a cross shape extending in the first horizontal direction (e.g., the X direction) and the second horizontal direction (e.g., the Y direction). However, this is only an example, and the void controllers 26 may have various shapes. The various other shapes of the void controllers 26 are described below with reference to FIGS. 3A, 3B, 3C, and 3D.

In addition, the void controllers 26 may have three shapes, such as a line shape extending in one direction, a line shape extending in the other direction, and/or a cross shape as shown, but this is only an example and the void controllers 26 may have one shape or two or more shapes. For example, the void controllers 26 may all have a line shape extending in one direction.

In this specification, among the void controllers 26, the void controller 26 facing the vertex of a chip edge CP_E may be referred to as a vertex void controller 26VT. In an embodiment, the vertex void controller 26VT may have a different shape from the other plurality of void controllers 26, but in another embodiment, the vertex void controller 26VT may have the same shape as the shape of the other plurality of void controllers 26.

The void controllers 26 may extend in the first horizontal direction (e.g., the X direction) and/or the second horizontal direction (e.g., the Y direction), and a horizontal length of the void controllers 26 extending in the first horizontal direction (e.g., the X direction) and/or the second horizontal direction (e.g., the Y direction) is not limited to the lengths shown. The void controllers 26 may overlap a plurality of bonding pads 22 in a plurality of rows and/or a plurality of columns in the first horizontal direction (e.g., the X direction) and/or the second horizontal direction (e.g., the Y direction), respectively. For example, the void controllers 26 may each overlap two rows and/or two columns of the plurality of bonding pads 22 in the first horizontal direction (e.g., the X direction) and/or the second horizontal direction (e.g., the Y direction).

The void controllers 26 may be arranged adjacent to the chip edge CP_E of the semiconductor chips CP. In some embodiments, one end of each of the void controllers 26 may face the chip edge CP_E and may be spaced apart from the chip edge CP_E with a portion of the bonding insulating layer 24 therebetween.

The void controllers 26 may control bonding defects or voids that may occur during a process of bonding the semiconductor chips CP to each other. Due to surface roughness of the semiconductor chips CP, bonding defects or voids may be inevitably formed when bonding the semiconductor chips CP. However, a position in which bonding defects or voids are formed may be controlled through the void controllers 26, and thus, formation of bonding defects or voids in positions other than the positions in which the void controllers 26 are formed may be reduced or prevented.

FIG. 3A is a schematic plan view illustrating a bonding structure 10a according to an embodiment.

Referring to FIG. 3A, the bonding structure 10a is substantially the same as the bonding structure 10 described above with reference to FIGS. 1 and 2, but different in that the bonding structure 10a includes a plurality of void controllers 26a, instead of the void controllers 26, so the difference from the bonding structure 10 is mainly described hereinafter.

The void controllers 26a may have a line shape extending in the first horizontal direction (e.g., the X direction), a line shape extending in the second horizontal direction (e.g., the Y direction), and/or a line shape extending diagonally between the first horizontal direction (e.g., the X direction) and the second horizontal direction (e.g., the Y direction).

In an embodiment, among the void controllers 26, the void controller corresponding to the vertex void controller 26VT of FIG. 2 may have a line-type layout extending diagonally.

FIG. 3B is a schematic plan view illustrating the bonding structure 10b according to an embodiment.

Referring to FIG. 3B, the bonding structure 10b is substantially the same as the bonding structure 10 described above with reference to FIGS. 1 and 2, but different in that the bonding structure 10b includes a plurality of void controllers 26b, instead of the void controllers 26, so the difference from the bonding structure 10 is mainly described hereinafter.

In some embodiments, a portion of the bonding insulating layer 24 and the void controller 26b may be located between some of the bonding pads 22. In addition, only a portion of the bonding insulating layer 24 may be located between other bonding pads 22, and the void controller 26b may be omitted. In an embodiment, only a portion of the bonding insulating layer 24 may be located between the bonding pads 22 closest to the chip edge CP_E, and the void controller 26b is omitted. For example, as shown in FIG. 3B, only a portion of the bonding insulating layer 24 may be located between the vertices of the chip edge CP_E and the bonding pads 22 adjacent to the vertices, and the void controller 26b may be omitted.

FIG. 3C is a schematic plan view illustrating a bonding structure 10c according to an embodiment.

Referring to FIG. 3C, the bonding structure 10c is substantially the same as the bonding structure 10 described above with reference to FIGS. 1 and 2, but different in that the bonding structure 10c includes a plurality of void controllers 26c, instead of the void controllers 26, so the difference from the bonding structure 10 is mainly described hereinafter.

As described above with reference to FIGS. 1 and 2, the void controllers 26c may extend in the first horizontal direction (e.g., the X direction) and/or the second horizontal direction (e.g., the Y direction), and a horizontal length of the void controllers 26c extending in the first horizontal direction (e.g., the X direction) and/or the second horizontal direction (e.g., the Y direction) is not limited to the lengths shown.

In some embodiments, the void controllers 26c may each overlap one row and/or one column of bonding pads 22 in the first horizontal direction (e.g., the X direction) and/or the second horizontal direction (e.g., the Y direction). For example, the void controllers 26c may each overlap one row and/or one column of bonding pads 22 in the first horizontal direction (e.g., the X direction) and/or the second horizontal direction (e.g., the Y direction). In other embodiments, although not illustrated, the void controllers 26c may each overlap two rows and/or two columns of bonding pads 22 in the first horizontal direction (e.g., the X direction). and/or the second horizontal direction (e.g., the Y direction).

The bonding pads 22 may include a plurality of outer bonding pads 22E that are closest to the chip edge CP_E, among the bonding pads 22, and a plurality of inner bonding pads 22C apart from the chip edge CP_E with the outer bonding pads 22E therebetween.

The void controllers 26c may include a plurality of outer void controllers 26O. The outer void controllers 26O may be located between the chip edge CP_E and the outer bonding pads 22E. The outer void controller 26O may be spaced apart from the adjacent outer bonding pad 22E with a portion of the bonding insulating layer 24 therebetween. In an embodiment, the outer void controllers 26O may be arranged adjacent to the vertex of the chip edge CP_E, but this is an example, and the outer void controllers 26O may not be limited to be arranged in the position adjacent to the vertex of the chip edge CP_E. For example, the outer void controllers 26O may be arranged adjacent to each side of the chip edge CP_E.

FIG. 3D is a schematic plan view illustrating a bonding structure 10d according to an embodiment.

Referring to FIG. 3D, the bonding structure 10d is substantially the same as the bonding structure 10 described above with reference to FIGS. 1 and 2, but different in that the bonding structure 10d includes a plurality of void controllers 26d, instead of the void controllers 26, so the difference from the bonding structure 10 is mainly described hereinafter.

As described above with reference to FIGS. 1 and 2, the void controllers 26d may extend in the first horizontal direction (e.g., the X direction) and/or the second horizontal direction (e.g., the Y direction), and a horizontal length of the voice controllers 26d extending in the first horizontal direction (e.g., the X direction) and/or the second horizontal direction (e.g., the Y direction) is not limited to the lengths shown.

In some embodiments, the void controllers 26d may each overlap one row and/or one column of bonding pads 22 in the first horizontal direction (e.g., the X direction) and/or the second horizontal direction (e.g., the Y direction). For example, the void controllers 26d may each overlap one row and/or one column of the bonding pads 22 in the first horizontal direction (e.g., the X direction) and/or the second horizontal direction (e.g., the Y direction).

The bonding pads 22 may include a plurality of outer bonding pads 22E that are closest to the chip edge CP_E, among the bonding pads 22, and a plurality of inner bonding pads 22C apart from the chip edge CP_E with the outer bonding pads 22E therebetween.

The void controllers 26d may include a plurality of inner void controllers 26I. The inner void controllers 26I may be located between the outer bonding pads 22E and the inner bonding pads 22C adjacent thereto and between the inner bonding pads 22C. The inner void controller 26I may be spaced apart from the bonding pads 22 with a portion of the bonding insulating layer 24 therebetween. In some cases, bonding defects or voids may occur in a center region of the semiconductor chip CP, rather than in the edge region adjacent to the chip edge CP_E of the semiconductor chip CP. In this case, the inner void controllers 26I may control bonding defects or voids that may occur in the central region of the semiconductor chip CP.

The void controllers 26d may include a plurality of outer void controllers 26O. The outer void controllers 26O may be located between the chip edge CP_E and the outer bonding pads 22E. The outer void controller 26O may be spaced apart from the adjacent outer bonding pad 22E with a portion of the bonding insulating layer 24 therebetween. In an embodiment, the outer void controllers 26O may be arranged adjacent to the vertex of the chip edge CP_E but this is an example, and the outer void controllers 26O are not limited to being located in a position adjacent to the vertex of the chip edge CP_E. For example, the outer void controllers 26O may be arranged adjacent to each side of the chip edge CP_E.

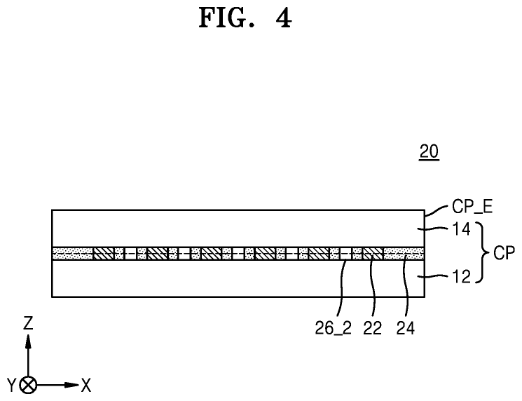

FIG. 4 is a schematic cross-sectional view illustrating a bonding structure 20 according to an embodiment.

Referring to FIG. 4, compared to the bonding structure 10 including the void controllers 26 described above with reference to FIGS. 1 and 2, the bonding structure 20 includes a plurality of void controllers 26_2, so the difference from the bonding structure 10 is mainly described hereinafter.

The void controllers 26_2 may be located between a pair of adjacent bonding pads 22 among the bonding pads 22. The void controller 26_2 may be spaced apart from the bonding pads 22 with a portion of the bonding insulating layer 24 therebetween.

In some embodiments, the void controllers 26_2 may be defined by the bonding insulating layer 24 and two semiconductor chips CP apart from each other with the bonding insulating layer 24 therebetween. The void controllers 26_2 may include a cavity closed by two semiconductor chips CP apart from each other with the bonding insulating layer 24 therebetween. In an embodiment as shown in FIG. 4, the void controllers 26_2 may be defined by the bonding insulating layer 24, the lower semiconductor chip 12, and the upper semiconductor chip 14. The void controllers 26_2 may include a cavity closed by the bonding insulating layer 24, the lower semiconductor chip 12, and the upper semiconductor chip 14. In some embodiments, a vertical length of the void controllers 26_2 in the vertical direction (e.g., the Z direction) may be substantially equal to a vertical length of the bonding insulating layer 24 in the vertical direction (e.g., the Z direction).

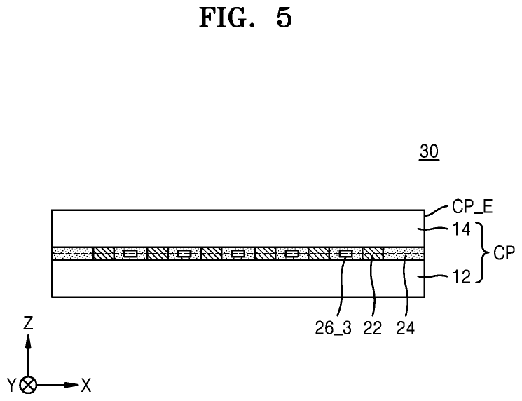

FIG. 5 is a schematic cross-sectional view illustrating a bonding structure 30 according to an embodiment.

Referring to FIG. 5, compared to the bonding structure 10 including the void controllers 26 described above with reference to FIGS. 1 and 2, the bonding structure 30 includes a plurality of void controllers 26_3, so the difference from the bonding structure 10 is mainly described hereinafter.

The void controllers 26_3 may be located between a pair of neighboring ones of the bonding pads 22. The void controller 26_3 may be spaced apart from the bonding pads 22 with a portion of the bonding insulating layer 24 therebetween.

In some embodiments, the void controllers 26_3 may include a cavity of which the surface is entirely surrounded and closed by (e.g., defined by) the bonding insulating layer 24. In an embodiment, as shown in FIG. 5, the void controllers 26_3 may be spaced apart from the lower semiconductor chip 12 with a portion of the bonding insulating layer 24 therebetween and may be spaced apart from the upper semiconductor chip 14 with a portion of the bonding insulating layer 24 therebetween. In some embodiments, a vertical length of the void controllers 26_3 in the vertical direction (e.g., the Z direction) may be less than a vertical length of the bonding insulating layer 24 in the vertical direction (e.g., the Z direction).

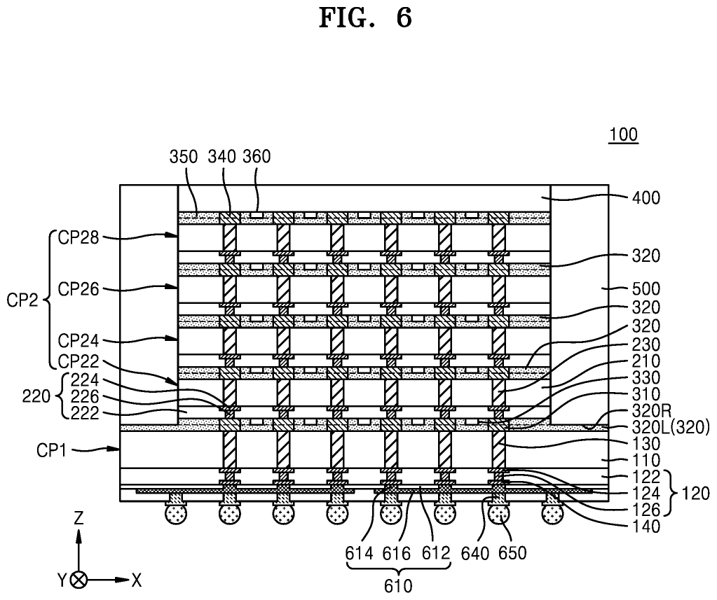

FIG. 6 is a cross-sectional view illustrating a semiconductor package 100 according to an embodiment.

Referring to FIG. 6, the semiconductor package 100 includes a first semiconductor chip CP1 and a plurality of second semiconductor chips CP2. In FIG. 6, the semiconductor package 100 is shown as including four second semiconductor chips CP2, but embodiments of the present disclosure are not limited thereto. For example, the semiconductor package 100 may include two or more second semiconductor chips CP2. In some embodiments, the semiconductor package 100 may include a multiple of four second semiconductor chips CP2.

A plurality of second semiconductor chips CP2 may be sequentially stacked on the first semiconductor chip CP1. For example, as shown in FIG. 6, a second semiconductor chip CP22 may be stacked on the first semiconductor chip CP1, a second semiconductor chip CP24 may be stacked on the second semiconductor chip CP22, a second semiconductor chip CP26 may be stacked on the second semiconductor chip CP24, and a second semiconductor chip CP28 may be stacked on the second semiconductor chip CP26. In this specification, for convenience of description, among the second semiconductor chips CP2, the second semiconductor chip CP22 located at the bottom, among the second semiconductor chips CP2, and located on the first semiconductor chip CP1 may be defined as the lowermost second semiconductor chip, and the second semiconductor chip CP28 located at the top, among the second semiconductor chips CP2, may be defined as the uppermost second semiconductor chip.

The first semiconductor chip CP1 may include a first semiconductor substrate 110 having an active surface and an inactive surface opposite to each other, a first individual device disposed on the active surface of the first semiconductor substrate 110, a first interconnection structure 120 disposed on the active surface of the first semiconductor substrate 110, and a plurality of first through-electrodes 130 connected to the first interconnection structure 120 and passing through the first semiconductor substrate 110. The first interconnection structure 120 may include a first interconnection layer 122, a first interconnection pattern 124, and a first interconnection via 126.

The first semiconductor chip CP1 may further include a plurality of chip pads 140 disposed on a lower surface of the first semiconductor substrate 110 and electrically connected to the first interconnection structure 120. The chip pads 140 may be electrically connected to the first interconnection pattern 124 and/or the first interconnection via 126 and may be electrically connected to the first individual device by the first interconnection pattern 124 and/or the first interconnection via 126.

Within the semiconductor package 100, the first semiconductor chip CP1 may be disposed such that the active surface of the first semiconductor substrate 110 faces the bottom and the inactive surface faces the top.

Each second semiconductor chip CP2 may include a second semiconductor substrate 210 having an active surface and an inactive surface opposite to each other, a second individual device disposed on the active surface of the second semiconductor substrate 210, a second interconnection structure 220 disposed on the active surface of the second semiconductor substrate 210, and a plurality of second through-electrodes 230 connected to the second interconnection structure 220 and passing through the second semiconductor substrate 210. The second interconnection structure 220 may include a second interconnection layer 222, a second interconnection pattern 224, and a second interconnection via 226.

Within the semiconductor package 100, the second semiconductor chip CP2 may be arranged such that the active surface of the second semiconductor substrate 210 faces the bottom and the inactive surface faces the top. For example, the second semiconductor chip CP2 may be arranged such that the active surface of the second semiconductor substrate 210 faces the inactive surface of the first semiconductor chip CP1.

The first semiconductor substrate 110 and the second semiconductor substrate 210 may include a semiconductor material such as, for example, silicon (Si). Alternatively, the first semiconductor substrate 110 and the second semiconductor substrate 210 may include a semiconductor material, such as germanium (Ge). The first semiconductor substrate 110 and the second semiconductor substrate 210 may include a conductive region such as, for example, a well doped with impurities. The first semiconductor substrate 110 and the second semiconductor substrate 210 may have various device isolation structures, such as a shallow trench isolation (STI) structure.

Each of the first individual device and the second individual device may include a plurality of various types of individual devices. The individual devices may include various microelectronic devices such as, for example, a metal-oxide-semiconductor field effect transistor (MOSFET) (e.g., a complementary metal-oxide-semiconductor (CMOS) transistor), an image sensor (e.g., a system large scale integration (LSI), a CMOS imaging sensor (CIS), etc.), a micro-electro-mechanical system (MEMS), an active device, a passive device, etc.

Each of the first and second individual devices may further include a conductive interconnection or a conductive plug. By the conductive interconnection or conductive plug, the individual devices included in the first individual device or the second individual device may be electrically connected to a conductive region of the first semiconductor substrate 110 or the second semiconductor substrate 210. The individual devices may be electrically separated from other neighboring individual devices by an insulating film.

The first semiconductor chip CP1 or the second semiconductor chip CP2 may be a memory semiconductor chip. In some embodiments, the first semiconductor chip CP1 may include a serial-parallel conversion circuit and may be a buffer chip for controlling the second semiconductor chips CP2. In addition, the second semiconductor chips CP2 may be memory chips including memory cells. For example, the semiconductor package 100 including the first semiconductor chip CP1 and a plurality of second semiconductor chips CP2 may be a high bandwidth memory (HBM), the first semiconductor chip CP1 may be an HBM controller die, and each of the second semiconductor chips CP2 may be a dynamic random-access memory (DRAM) die.

The first interconnection structure 120 may include a first interconnection layer 122, a plurality of first interconnection patterns 124 surrounded by the first interconnection layer 122, and a plurality of first interconnection vias 126 electrically connected to the first interconnection patterns 124. In some embodiments, the first interconnection patterns 124 and the first interconnection vias 126 may be at different vertical levels, and the first interconnection structure 120 may form a multilayer interconnection structure.

The second interconnection structure 220 may include a second interconnection layer 222, a plurality of second interconnection patterns 224 surrounded by the second interconnection layer 222, and a plurality of second interconnection vias 226 electrically connected to the second interconnection patterns 224. In some embodiments, the second interconnection patterns 224 and the second interconnection vias 226 may be at different vertical levels, and the second interconnection structure 220 may form a multilayer interconnection structure.

When the first interconnection structure 120 and the second interconnection structure 220 have a multilayer interconnection structure, the first interconnection layer 122 and the second interconnection layer 222 may have a multilayer structure in which a plurality of insulating layers are stacked to correspond to the multilayer interconnection structure.

In some embodiments, the first interconnection layer 122 and the second interconnection layer 222 may include an insulating material. For example, the first interconnection layer 122 and the second interconnection layer 222 may include silicon oxide, silicon nitride, silicon oxynitride, an insulating material with a lower dielectric constant than silicon oxide, or combinations thereof. In some embodiments, the first interconnection layer 122 and the second interconnection layer 222 may include a tetraethyl orthosilicate (TEOS) film or an ultralow K (ULK) film having an ultralow dielectric constant K of about 2.2 to 2.4. The ULK film may include a SiOC film or a SiCOH film.

In some embodiments, the first interconnection pattern 124, the first interconnection via 126, the second interconnection pattern 224, and the second interconnection via 226 may include a conductive material. For example, the first interconnection pattern 124, the first interconnection via 126, the second interconnection pattern 224, and the second interconnection via 226 may include aluminum, copper, or tungsten. In some embodiments, the first interconnection pattern 124, the first interconnection via 126, the second interconnection pattern 224, and the second interconnection via 226 may include a barrier film for interconnection and a metal layer for interconnection. The barrier film for interconnection may include metal, metal nitride, or an alloy. The metal layer for interconnection may include at least one metal selected from among W, Al, Ti, Ta, Ru, Mn, and Cu.

In some embodiments, each of the first through-electrodes 130 and the second through-electrodes 230 may include a through silicon via (TSV). Each of the first through-electrodes 130 and the second through-electrodes 230 may include a conductive plug, passing through each of the first semiconductor substrate 110 and the second semiconductor substrate 210, and a conductive barrier film surrounding the conductive plug. The conductive plug may have a cylindrical shape, and the conductive barrier film may have a cylindrical shape surrounding a sidewall of the conductive plug. A via insulating film may be located between the first through-electrode 130 and the first semiconductor substrate 110 and between the second through-electrode 230 and the second semiconductor substrate 210 to surround sidewalls of the first through-electrode 130 and the second through-electrode 230. The first through-electrode 130 and the second through-electrode 230 may be formed as one from among a via-first, via-middle, and via-last structures.

The first semiconductor chip CP1 and each of the second semiconductor chips CP2 may be electrically connected through a plurality of bonding pads 310 to exchange signals and provide power and ground to each other. The bonding pads 310 may be located between the first semiconductor chip CP1 and the lowermost second semiconductor chip (e.g., the second semiconductor chip CP22) and between the second semiconductor chips CP2 that are adjacent to each other. A bonding insulating layer 320 may be located between the first semiconductor chip CP1 and the lowermost second semiconductor chip (e.g., the second semiconductor chip CP22) and between the second semiconductor chips CP2 that are adjacent to each other, and may be located to surround the bonding pads 310. The bonding pads 310 may be surrounded planarly by the bonding insulating layer 320.

The bonding pads 310 may be located between the first through-electrode 130 and the second interconnection pattern 224 and/or the second interconnection via 226 of the second interconnection structure 220, and between the second through-electrode 230 of one of the second semiconductor chips CP2 and the second interconnection pattern 224 and/or the second interconnection via 226 of the second interconnection structure 220 of another one of the second semiconductor chips CP2, respectively. The bonding pads 310 may electrically connect the second interconnection pattern 224 and/or the second interconnection via 226 of the second interconnection structure 220 of one of the second semiconductor chips CP2 to the first through-electrode 130 of the first semiconductor chip CP1 or the second through-electrode 230 of another one of the second semiconductor chips CP2. For example, the bonding pads 310 may electrically connect the first through-electrodes 130 of the first semiconductor chip CP1 to the second through-electrodes 230 of each of the second semiconductor chips CP2.

In some embodiments, the bonding pads 310 may be formed through diffusion bonding of forming conductive material layers on surfaces of two adjacent chips, among the first semiconductor chip CP1 and the second semiconductor chips CP2, respectively, expanding the conductive material layers by heat to contact each other, and then diffusing metal atoms in the conductive material layers so that the conductive material layers are integrated with each other. The method of forming the bonding pads 310 is described in detail below with respect to a manufacturing process.

In some embodiments, the bonding insulating layer 320 may be formed through diffusion bonding of forming insulating material layers on surfaces of two adjacent chips, among the first semiconductor chip CP1 and the second semiconductor chips CP2, respectively, expanding the insulating material layers by heat to contact each other, and then diffusing metal atoms in the insulating material layers so that the insulating material layers are integrated with each other. The method of forming the bonding insulating layer 320 is described in detail below with respect to the manufacturing process.

Among the bonding insulating layers 320, the bonding insulating layer 320 located between the first semiconductor chip CP1 and the lowermost second semiconductor chip (e.g., the second semiconductor chip CP22) may be referred to as the lowermost bonding insulating layer 320L.

The lowermost bonding insulating layer 320L may include a portion that overlaps with the lowermost second semiconductor chip (e.g., the second semiconductor chip CP22) in the vertical direction (e.g., the Z direction) and a portion that does not overlap with the lowermost second semiconductor chip (e.g., the second semiconductor chip CP22) in the vertical direction (e.g., the Z direction).

A height of the portion of the lowermost bonding insulating layer 320L that overlaps with the lowermost second semiconductor chip (e.g., the second semiconductor chip CP22) in the vertical direction (e.g., the Z direction) may be greater than a height of the portion of the lowermost bonding insulating layer 320L that does not overlap with the lowermost second semiconductor chip (e.g., the second semiconductor chip CP22). For example, the lowermost bonding insulating layer 320L may include a recess 320R in the portion of the lowermost bonding insulating layer 320L that does not overlap with the lowermost second semiconductor chip (e.g., the second semiconductor chip CP22). At an upper surface of the lowermost bonding insulating layer 320L, due to the recess 320R, the portion that overlaps with the lowermost second semiconductor chip (e.g., the second semiconductor chip CP22) may protrude upwardly, relative to the portion thereof that does not overlap with the lowermost second semiconductor chip (e.g., the second semiconductor chip CP22).

The lowermost bonding insulating layer 320L may cover a portion of the upper surface of the first semiconductor chip CP1 that does not overlap with the lowermost second semiconductor chip (e.g., the second semiconductor chip CP22). The lowermost bonding insulating layer 320L may cover a portion of the upper surface of the first semiconductor chip CP1 that is not covered by the bonding pads 310, in the portion of the upper surface of the first semiconductor chip CP1 that overlaps with the lowermost second semiconductor chip (e.g., the second semiconductor chip CP22).

Bonding insulating layers 320 other than the lowermost bonding insulating layer 320L may cover a portion, not covered by the bonding pads 310, in the upper surface and lower surface of the second semiconductor chip CP2.

A plurality of first void controllers 330 may be located between the first semiconductor chip CP1 and the lowermost second semiconductor chip (e.g., the second semiconductor chip CP22) and between the second semiconductor chips CP2 adjacent to each other. The first void controllers 330 may correspond to the void controllers 26, 26a, 26b, 26c, 26d, 26_2, and 26_3 described above with reference to FIGS. 1, 2, 3A, 3B, 3C, 3D, 4, and 5. The first void controllers 330 are described in detail in descriptions of the void controllers 26, 26a, 26b, 26c, 26d, 26_2, and 26_3 provided above with reference to FIGS. 1, 2, 3A, 3B, 3C, 3D, 4, and 5, and thus are described briefly hereinafter.

The first void controllers 330 may be located between a pair of bonding pads 310 adjacent to each other, among the bonding pads 310. Each of the first void controllers 330 may be spaced apart from the bonding pad 310 adjacent to the first void controller 330 with a portion of the bonding insulating layer 320 therebetween.

The first void controllers 330 may be defined by the bonding insulating layer 320, the first semiconductor chip CP1, and/or at least one second semiconductor chip CP2, and may include a cavity closed by the bonding insulating layer 320, the first semiconductor chip CP1, and/or at least one second semiconductor chip CP2.

In an embodiment, the first void controllers 330 may include a cavity closed (e.g., defined) by the bonding insulating layer 320. In another embodiment, the first void controllers 330 may include a cavity closed (e.g., defined) by the bonding insulating layer 320 and the first semiconductor chip CP1. For example, the first void controllers 330 may expose a portion of an upper surface of the first semiconductor chip CP1. In addition, the first void controllers 330 may include a cavity closed (e.g., defined) by the bonding insulating layer 320 and the second semiconductor chip CP2. For example, the first void controllers 330 may expose a portion of the upper surface or a portion of a lower surface of the second semiconductor chip CP2.

In another embodiment, the first void controllers 330 may include a cavity closed (e.g., defined) by the bonding insulating layer 320, the first semiconductor chip CP1, and the lowermost second semiconductor chip (e.g., the second semiconductor chip CP22), and a cavity closed (e.g., defined) by the bonding insulating layer and the second semiconductor chips CP2. For example, the first void controllers 330 may pass through the bonding insulating layer 320 in the vertical direction (e.g., the Z direction) and expose a portion of the upper surface of the first semiconductor chip CP1 and a portion of the lower surface of the lowermost second semiconductor chip (e.g., the second semiconductor chip CP22). The first void controllers 330 may pass through the bonding insulating layer 320 in the vertical direction (e.g., the Z direction) to expose a portion of the upper and lower surfaces of the second semiconductor chips CP2.

A dummy support substrate 400 may be disposed on the uppermost second semiconductor chip (e.g., the second semiconductor chip CP28). The dummy support substrate 400 may include, for example, a semiconductor material, such as silicon (Si). In some embodiments, the dummy support substrate 400 may include only a semiconductor material. For example, the dummy support substrate 400 may be a portion of a bare wafer.

In some embodiments, a horizontal width of the first semiconductor chip CP1 in the first horizontal direction (e.g., the X direction) may be equal to or greater than a horizontal width of the second semiconductor chips CP2 in the first horizontal direction (e.g., the X direction). For example, the horizontal width of the first semiconductor chip CP1 may be approximately 11 millimeters, and the horizontal width of the second semiconductor chips CP2 may be approximately 10 millimeters. In some embodiments, the horizontal width of the second semiconductor chips CP2 in the first horizontal direction (e.g., the X direction) may be equal to or greater than a horizontal width of the dummy support substrate 400 in the first horizontal direction (e.g., the X direction). For example, the horizontal width of the second semiconductor chips CP2 may be approximately 10 millimeters, and the horizontal width of the dummy support substrate 400 may be approximately 9 millimeters.

In some embodiments, a vertical length of the first semiconductor chip CP1 in the vertical direction (e.g., the Z direction) may be equal to or greater than a vertical length (e.g., thickness) of each of the second semiconductor chips CP2 in the vertical direction (e.g., the Z direction). For example, the vertical length (e.g., thickness) of the first semiconductor chip CP1 may be approximately 60 micrometers, and the vertical length (e.g., thickness) of each of the second semiconductor chips CP2 may be approximately 40 micrometers. In some embodiments, the vertical length (e.g., thickness) of the first semiconductor chip CP1 in the vertical direction (e.g., the Z direction) may be less than the vertical length (e.g., thickness) of the dummy support substrate 400 in the vertical direction (e.g., the Z direction). For example, the vertical length (e.g., thickness) of the first semiconductor chip CP1 may be approximately 60 micrometers, and the vertical length (e.g., thickness) of the dummy support substrate 400 may be approximately 200 micrometers.

A plurality of support bonding pads 340 and a support bonding insulating layer 350 may be located between the uppermost second semiconductor chip (e.g., second semiconductor chip CP28) and the dummy support substrate 400. The support bonding pads 340 may be surrounded planarly by the support bonding insulating layer 350. The support bonding insulating layer 350 may be located to surround the support bonding pads 340 between the uppermost second semiconductor chip (e.g., the second semiconductor chip CP28) and the dummy support substrate 400. The support bonding insulating layer 350 may cover a portion of the upper surface of the uppermost second semiconductor chip (e.g., the second semiconductor chip CP28) and portions of the lower surface of the dummy support substrate 400 that are not covered by the support bonding pads 340.

In some embodiments, the support bonding pads 340 may be formed through diffusion bonding of forming conductive material layers on the upper surface of the uppermost second semiconductor chip (e.g., the second semiconductor chip CP28) and the lower surface of the dummy support substrate 400 facing each other, respectively, expanding the conductive material layers by heat to contact each other, and then diffusing metal atoms in the conductive material layers so that the conductive material layers are integrated with each other. The method of forming the support bonding pads 340 is described in detail below with respect to the manufacturing process.

In some embodiments, the support bonding insulating layer 350 may be formed through diffusion bonding including forming insulating material layers on the upper surface of the uppermost second semiconductor chip (e.g., the second semiconductor chip CP28) and the lower surface of the dummy support substrate 400 facing each other, respectively, expanding the insulating material layers by heat to contact each other, and then diffusing metal atoms in the insulating material layers so that the insulating material layers are integrated with each other. The method of forming the support bonding insulating layer 350 is described in detail below with respect to the manufacturing process.

A plurality of second void controllers 360 may be located between the uppermost second semiconductor chip (e.g., the second semiconductor chip CP28) and the dummy support substrate 400. Similar to the first void controller 330, the second void controllers 360 may correspond to the void controllers 26, 26a, 26b, 26c, 26d, 26_2, and 26_3 described above with reference to FIGS. 1, 2, 3A, 3B, 3C, 3D, 4, and 5. The second void controllers 360 are described in detail in descriptions of the void controllers 26, 26a, 26b, 26c, 26d, 26_2, and 26_3 described above with reference to FIGS. 1, 2, 3A, 3B, 3C, 3D, 4, and 5, and thus are described briefly hereinafter.

The second void controllers 360 may be located between adjacent ones of the support bonding pads 340. Each of the second void controllers 360 may be spaced apart from the support bonding pad 340 adjacent to the second void controller 360 with a portion of the support bonding insulating layer 350 therebetween.

The second void controllers 360 may be defined by the support bonding insulating layer 350, the uppermost second semiconductor chip (e.g., the second semiconductor chip CP28), and/or the dummy support substrate 400, and may include a cavity closed by (e.g., defined by) the support bonding insulating layer 250, the uppermost second semiconductor chip (e.g., the second semiconductor chip CP28), and/or the dummy support substrate 400.

In an embodiment the second void controllers 360 may include a cavity closed by (e.g., defined by) the support bonding insulating layer 350. In another embodiment, the second void controllers 360 may include a cavity closed by (e.g., defined by) the support bonding insulating layer 350 and the uppermost second semiconductor chip (e.g., the second semiconductor chip CP28). For example, the second void controllers 360 may face a portion of the upper surface of the uppermost second semiconductor chip (e.g., the second semiconductor chip CP28). In addition, the second void controllers 360 may include a cavity closed by (e.g., defined by) the bonding insulating layer 320 and the dummy support substrate 400. For example, the second void controllers 360 may face a portion of the lower surface of the dummy support substrate 400.

In another embodiment, the second void controllers 360 may include a cavity closed by (e.g., defined by) the support bonding insulating layer 350, the uppermost second semiconductor chip (e.g., the second semiconductor chip CP28), and the dummy support substrate 400. For example, the second void controllers 360 may pass through the support bonding insulating layer 350 in the vertical direction (e.g., the Z direction) to expose a portion of the upper surface of the uppermost second semiconductor chip (e.g., the second semiconductor chip CP28) and a portion of the lower surface of the dummy support substrate 400.

In some embodiments, the bonding pads 310 and the support bonding pads 340 may include a material capable of diffusion bonding, such as Cu, Al, or W. In some embodiments, the bonding insulating layer 320 and the support bonding insulating layer 350 may include any one from among SiO, SiN, SiCN, SiCO, and a polymer material. The polymer material may include benzocyclobutene (BCB), polyimide (PI), polybenzoxazole (PBO), silicone, acrylate, or epoxy. For example, the bonding insulating layer 320 and the support bonding insulating layer 350 may include silicon oxide. In some embodiments, the bonding insulating layer 320 and the support bonding insulating layer 350 may include the same material as each other. The bonding insulating layer 320 and the support bonding insulating layer 350 may have a thickness of, for example, about 100 nanometers to about 1 micrometer.

In this specification, the first void controllers 330 and the second void controllers 360 may be referred to as a plurality of void controllers. Each of the void controllers may have various shapes such as, for example, a slit shape, a groove shape, or a recess shape. Each of the void controllers may include a cavity filled with a substantially inert gas or gaseous material (including, but not limited to, air).

The void controllers may control bonding defects or voids that may occur in the process of bonding the first semiconductor chip CP1 to the lowermost second semiconductor chip (e.g., the second semiconductor chip CP22) and bonding the second semiconductor chips CP2. Due to surface roughness of the first semiconductor chip CP1 and the second semiconductor chips CP2, bonding defects or voids may be inevitably formed when bonding the first semiconductor chip CP1 to the second semiconductor chips CP2. However, a position in which bonding defects or voids are formed may be controlled through the void controllers, and thus, formation of bonding defects or voids in positions other than the position in which the void controllers are formed may be reduced or prevented.

The semiconductor package 100 may include a package molding layer 500 that covers a portion of the upper surface of the first semiconductor chip CP1 that is not covered by the lowermost second semiconductor chip (e.g., the second semiconductor chip CP22). The package molding layer 500 may surround sidewalls of the second semiconductor chips CP2 and a sidewall of the dummy support substrate 400. The package molding layer 500 may include, for example, epoxy mold compound (EMC).

The package molding layer 500 is shown not covering the upper surface of the dummy support substrate 400, but the package molding layer 500 is not limited thereto and may extend to cover the upper surface of the dummy support substrate 400.

In some embodiments, the semiconductor package 100 may further include a base redistribution layer 610 disposed on the lower surface of the first semiconductor chip CP1. The base redistribution layer 610 may include a package redistribution insulating layer 612, a plurality of package redistribution vias 614, and a package redistribution line pattern 616.

In some embodiments, a plurality of package redistribution insulating layers 612 may be stacked. Each package redistribution insulating layer 612 may be formed from, for example, photo imageable dielectric (PID) or photosensitive polyimide (PSPI).

The package redistribution via 614 may be connected to the package redistribution line pattern 616 through the package redistribution insulating layer 612. The package redistribution via 614 may be surrounded planarly by the package redistribution insulating layer 612. In some embodiments, a plurality of package redistribution line patterns 616 may be stacked. Each of the package redistribution line patterns 616 may be disposed on the package redistribution insulating layer 612. In some embodiments, a plurality of package redistribution vias 614 may be integrally formed with the package redistribution line pattern 616.

The package redistribution via 614 and the package redistribution line pattern 616 may include metals, such as copper (Cu), aluminum (Al), tungsten (W), titanium (Ti), indium (In), and molybdenum (Mo), manganese (Mn), cobalt (Co), tin (Sn), nickel (Ni), magnesium (Mg), rhenium (Re), beryllium (Be), gallium (Ga), ruthenium (Ru), or alloys thereof, but are not limited to these. In some embodiments, the package redistribution via 614 and the package redistribution line pattern 616 may be formed by stacking a metal or metal alloy on a seed layer including titanium, titanium nitride, or titanium tungsten.

The package redistribution vias 614 and the package redistribution line pattern 616 may be electrically connected to the chip pads 140. In some embodiments, at least some of the package redistribution vias 614 may contact the chip pads 140. For example, when a plurality of package redistribution insulating layers 612 are included, the package redistribution via 614 passing through the uppermost one of the package redistribution insulating layers 612 may contact the chip pad 140.

In some embodiments, the package redistribution vias 614 may have a tapered shape extending from the bottom to the top with a narrowing horizontal width. For example, the horizontal width of the package redistribution vias 614 may increase in a direction away from the first semiconductor chip CP1.

A package pad 640 may be disposed on a lower surface of the base redistribution layer 610. In some embodiments, the package pad 640 may include the same material as the material of the package redistribution line pad. The package pad 640 may be provided in plural, and the plurality of package pads 640 may contact a plurality of package connection terminals 650, respectively. For example, each of the package connection terminals 650 may be a solder ball or a bump.

In some embodiments, the semiconductor package 100 may not include the base redistribution layer 610. For example, the package connection terminals 650 may be attached to a plurality of chip pads 140.

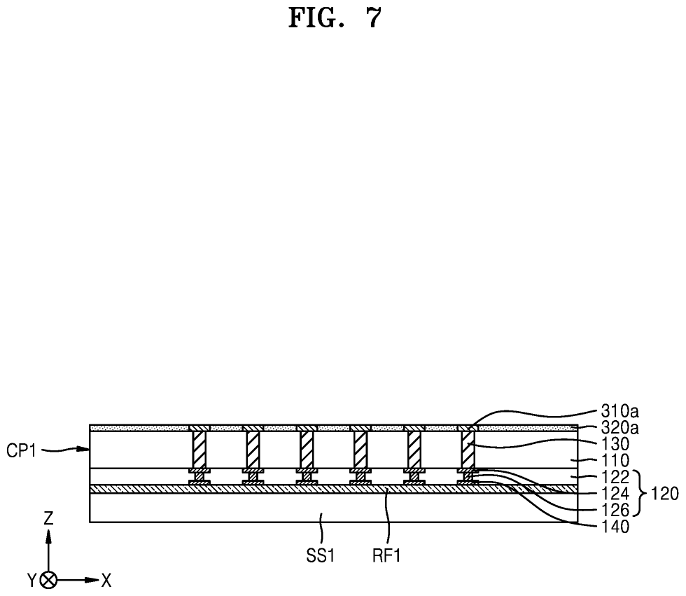

FIGS. 7, 8, 9, 10, and 11 are cross-sectional view illustrating a sequential process of a method of manufacturing a semiconductor package according to an embodiment.

Referring to FIG. 7, the first semiconductor chip CP1 is attached to a first support substrate SS1. The first semiconductor chip CP1 may be attached to a first release film RF1 after the first release film RF1 is attached to an upper surface of the first support substrate SS1. The first semiconductor chip CP1 may be attached to the first release film RF1 so that the first interconnection structure 120 faces the first support substrate SS1. The chip pads 140 exposed on or at the lower surface of the first semiconductor substrate 110 may be attached to the first release film RF1.

Thereafter, a plurality of first preliminary bonding pads 310a and a first preliminary bonding insulating layer 320a may be formed on the upper surface of the first semiconductor chip CP1. The first preliminary bonding pads 310a may be disposed on the upper surface, that is, the inactive surface, of the first semiconductor chip CP1. The first preliminary bonding pads 310a may be disposed on the upper surface of the first semiconductor chip CP1 to be connected to the first through-electrodes 130. The first preliminary bonding insulating layer 320a may be formed to surround side surfaces of the first preliminary bonding pads 310a on the upper surface, that is, the inactive surface, of the first semiconductor chip CP1. The first preliminary bonding insulating layer 320a may cover the upper surface of the first semiconductor chip CP1 and the side surfaces of the first preliminary bonding pads 310a but may not cover the upper surface of the first preliminary bonding pads 310a.

In detail, in order to form the first preliminary bonding insulating layer 320a, an insulating film covering the upper surface of the first semiconductor chip CP1 may be formed on the upper surface of the first semiconductor chip CP1. Thereafter, a plurality of local regions may be removed from the upper surface of the insulating film, and a plurality of first preliminary bonding pads 310a may be formed within the local regions.

In some embodiments, after the first preliminary bonding pads 310a are formed, the local regions may be removed from the upper surface of the insulating film and the first void controllers 330 may be formed within the local regions. In an embodiment, the upper surface of the first semiconductor chip CP1 may be exposed by removing the local regions from the upper surface of the insulating film. For example, the upper surface of the first semiconductor chip CP1 may be exposed by the first void controllers 330. In another embodiment, even if the local regions are removed from the upper surface of the insulating film, the upper surface of the first semiconductor chip CP1 may not be exposed and a portion of the insulating film may remain on the upper surface of the first semiconductor chip CP1. For example, the upper surface of the first semiconductor chip CP1 may not be exposed by the first void controllers 330 and the first preliminary bonding insulating layer 320a may be exposed.

The first void controllers 330 may be formed between the first preliminary bonding pads 310a and may be spaced apart from the first preliminary bonding pads 310a with a portion of the first preliminary bonding insulating layer 320a therebetween.

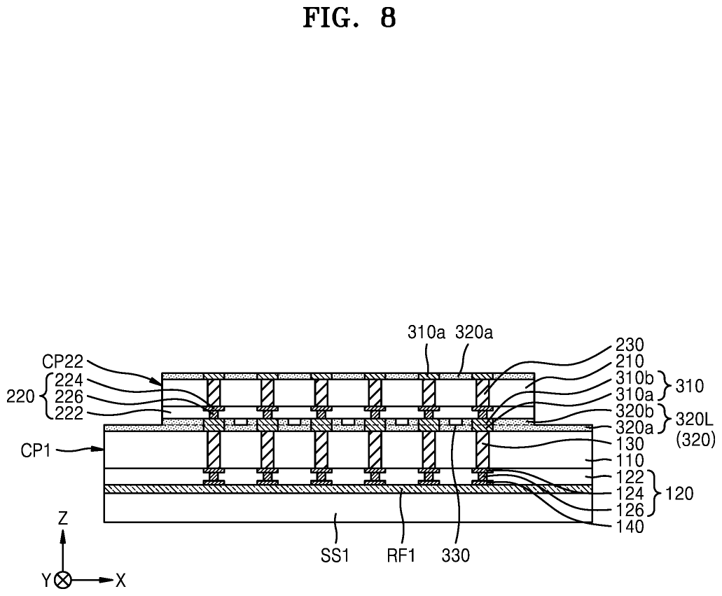

Referring to FIG. 8, a plurality of second preliminary bonding pads 310b and a second preliminary bonding insulating layer 320b may be formed on a lower surface of the lowermost second semiconductor chip (e.g., the second semiconductor chip CP22). The second preliminary bonding pads 310b may be disposed on the lower surface of the lowermost second semiconductor chip (e.g., the second semiconductor chip CP22), that is, on the lower surface of the second interconnection structure 220. The second preliminary bonding pads 310b may be disposed on the lower surface of the lowermost second semiconductor chip (e.g., the second semiconductor chip CP22) to be connected to the second interconnection pattern 224 and/or the second interconnection via 226. The second preliminary bonding insulating layer 320b may be formed to surround the side surfaces of the second preliminary bonding pads 310b on the lower surface of the lowermost second semiconductor chip (e.g., the second semiconductor chip CP22). The second preliminary bonding insulating layer 320b may cover the lower surface of the lowermost second semiconductor chip (e.g., the second semiconductor chip CP22) and the side surfaces of the second preliminary bonding pads 310b but may expose, instead of cover, the lower surface of the second preliminary bonding pads 310b.

In detail, in order to form the second preliminary bonding insulating layer 320b, an insulating film covering the lower surface of the lowermost second semiconductor chip (e.g., the second semiconductor chip CP22) may be formed on the lower surface of the lowermost second semiconductor chip (e.g., the second semiconductor chip CP22). Thereafter, local regions may be removed from the lower surface of the insulating film, and the second preliminary bonding pads 310b may be formed within the local regions.

In some embodiments, after forming the second preliminary bonding pads 310b, the local regions may be removed from the lower surface of the insulating film and the first void controllers 330 may be formed within the local regions. In an embodiment, the local regions may be removed from the lower surface of the insulating film so that the lower surface of the lowermost second semiconductor chip (e.g., the second semiconductor chip CP22) may be exposed. For example, the lower surface of the lowermost second semiconductor chip (e.g., the second semiconductor chip CP22) may be exposed by the first void controllers 330. In another embodiment, even if the local regions are removed from the lower surface of the insulating film, the lower surface of the lowermost second semiconductor chip (e.g., the second semiconductor chip CP22) may not be exposed and a portion of the insulating film may remain on the lower surface of the lowermost second semiconductor chip (e.g., the second semiconductor chip CP22). For example, the lower surface of the lowermost second semiconductor chip (e.g., the second semiconductor chip CP22) may not be exposed from the first void controllers 330, and a portion of the second preliminary bonding insulating layer 320b may be exposed.

The first void controllers 330 may be formed between the second preliminary bonding pads 310b and may be spaced apart from the second preliminary bonding pads 310b with a portion of the second preliminary bonding insulating layer 320b therebetween.

In other embodiments, in order to form a void controller corresponding to the void controller 26_2 of FIG. 4, as described above, the local regions may be removed from the upper surface of the insulating film covering the upper surface of the first semiconductor chip CP1 for forming the first preliminary bonding insulating layer 320a and the local regions may be removed from the lower surface of the insulating film covering the lower surface of the lowermost second semiconductor chip (e.g., the second semiconductor chip CP22) for forming the second preliminary bonding insulating layer 320b to form the first void controllers 330. In an embodiment, the upper surface of the first semiconductor chip CP1 and the lower surface of the lowermost second semiconductor chip (e.g., the second semiconductor chip CP22) may be exposed by removing the local regions. For example, the upper surface of the first semiconductor chip CP1 and the lower surface of the lowermost second semiconductor chip (e.g., the second semiconductor chip CP22) may be exposed through the first void controllers 330.

The first void controllers 330 may be formed between the first preliminary bonding pads 310a and the second preliminary bonding pads 310b and may be spaced apart from the first preliminary bonding pads 310a and the second preliminary bonding pads 310b with a portion of the first preliminary bonding insulating layer 320a and a portion of the second preliminary bonding insulating layer 320b therebetween.

In another embodiment, in order to form a void controller corresponding to the void controller 26_3 of FIG. 5, as described above, the local regions may be removed from the upper surface of the insulating film covering the upper surface of the first semiconductor chip CP1 for forming the first preliminary bonding insulating layer 320a and the local regions may be removed from the lower surface of the insulating film covering the lower surface of the lowermost second semiconductor chip (e.g., the second semiconductor chip CP22) for forming the second preliminary bonding insulating layer 320b to form the first void controllers 330 within the local regions. In an embodiment, even if the local regions are removed, the upper surface of the first semiconductor chip CP1 and the lower surface of the lowermost second semiconductor chip (e.g., the second semiconductor chip CP22) may not be exposed and a portion of the insulating film may remain on the upper surface of the first semiconductor chip CP1 and on the lower surface of the lowermost second semiconductor chip (e.g., the second semiconductor chip CP22). For example, through the first void controllers 330, the upper surface of the first semiconductor chip CP1 and the lower surface of the lowermost second semiconductor chip (e.g., the second semiconductor chip CP22) may not be exposed and a portion of the first preliminary bonding insulating layer 320a and a portion of the second preliminary bonding insulating layer 320b may be exposed.

The first void controllers 330 may be formed between the first preliminary bonding pads 310a and the second preliminary bonding pads 310b and may be spaced apart from the first preliminary bonding pads 310a and the second preliminary bonding pad 310b with a portion of the first preliminary bonding insulating layer 320a and a portion of the second preliminary bonding insulating layer 320b therebetween.

Thereafter, the lowermost second semiconductor chip (e.g., the second semiconductor chip CP22) may be aligned on the first semiconductor chip CP1 so that the first preliminary bonding pads 310a may face the second preliminary bonding pads 310b, and the first semiconductor chip CP1 may be bonded to the lowermost second semiconductor chip (e.g., the second semiconductor chip CP22). In some embodiments, the first preliminary bonding pads 310a may be bonded to the second preliminary bonding pads 310b and the first preliminary bonding insulating layer 320a may be bonded to the second preliminary bonding insulating layer 320b, by applying heat, pressure, or a combinations thereof.

In some embodiments, the lowermost second semiconductor chip (e.g., the second semiconductor chip CP22) may be located on the first semiconductor chip CP1 and heat at a first temperature may be applied thereto. Thereafter, the bonding pads 310 in which the first preliminary bonding pads 310a are coupled to the second preliminary bonding pads 310b, and the bonding insulating layer 320, in which the first preliminary bonding insulating layer 320a is coupled to the second preliminary bonding insulating layer 320b, may be formed by applying heat at a second temperature higher than the first temperature.

The first preliminary bonding pads 310a and the second preliminary bonding pads 310b corresponding to each other may be expanded by heat to contact each other, and then metal atoms may be diffused for bonding so that the first preliminary bonding pads 310a are integrated with the second preliminary bonding pads 310b to form the bonding pads 310. Similarly, the first preliminary bonding insulating layer 320a and the second preliminary bonding insulating layer 320b may be expanded by heat to contact each other, and then atoms may be diffused for bonding and integration to form the bonding insulating layer 320. In some embodiments, the first preliminary bonding pads 310a and the second preliminary bonding pads 310b and the first preliminary bonding insulating layer 320a and the second preliminary bonding insulating layer 320b may be bonded to form covalent bands. Accordingly, the lowermost second semiconductor chip (e.g., the second semiconductor chip CP22) may be directly bonded to the first semiconductor chip CP1 without a separate adhesive layer.

In some embodiments, before bonding the first preliminary bonding pads 310a and the second preliminary bonding pads 310b, a process of treating the surfaces of the first preliminary bonding pads 310a and the second preliminary bonding pads 310b with hydrogen plasma may be further performed to strengthen bonding strength thereof.

By bonding the first preliminary bonding pads 310a to the second preliminary bonding pads 310b, the first void controllers 330 may be formed as a cavity filled with an inert gas or gaseous material. In some embodiments, the first void controllers 330 may be a cavity closed by (e.g., defined by) the bonding insulating layer 320, the first semiconductor chip CP1 and the bonding insulating layer 320; the lowermost second semiconductor chip (e.g., the second semiconductor chip CP22) and the bonding insulating layer 320; or the first semiconductor chip CP1, the lowermost second semiconductor chip (e.g., the second semiconductor chip CP22), and the bonding insulating layer 320.

The width of the first preliminary bonding insulating layer 320a on the upper surface of the first semiconductor chip CP1 in the first horizontal direction (e.g., the X direction) may be equal to the horizontal width of the first semiconductor chip CP1 in the first horizontal direction (e.g., the X direction). The width of the second preliminary bonding insulating layer 320b on the lower surface of the lowermost second semiconductor chip (e.g., the second semiconductor chip CP22) in the first horizontal direction (e.g., the X direction) may be substantially equal to the horizontal width of the lowermost second semiconductor chip (e.g., the second semiconductor chip CP22) in the first horizontal direction (e.g., the X direction). Accordingly, a portion of the first preliminary bonding insulating layer 320a may contact the second preliminary bonding insulating layer 320b to form the bonding insulating layer 320, and the remainder of the first preliminary bonding insulating layer 320a may not contact the second preliminary bonding insulating layer 320b. A portion of the first preliminary bonding insulating layer 320a that contacts the second preliminary bonding insulating layer 320b may overlap with the lowermost second semiconductor chip (e.g., the second semiconductor chip CP22) in the vertical direction (e.g., the Z direction).

Thereafter, the first preliminary bonding pads 310a and the first preliminary bonding insulating layer 320a may be formed on the upper surface of the lowermost second semiconductor chip (e.g., the second semiconductor chip CP22). The first preliminary bonding pads 310a may be disposed on the upper surface, that is, the inactive surface, of the lowermost second semiconductor chip (e.g., the second semiconductor chip CP22). The first preliminary bonding pads 310a may be disposed on the upper surface of the lowermost second semiconductor chip (e.g., the second semiconductor chip CP22) to be connected to the second through-electrodes 230. The first preliminary bonding insulating layer 320a may be formed to surround the side surfaces of the first preliminary bonding pads 310a on the upper surface, that is, the inactive surface, of the lowermost second semiconductor chip (e.g., the second semiconductor chip CP22). The first preliminary bonding insulating layer 320a may cover the side surfaces of the lowermost second semiconductor chip (e.g., the second semiconductor chip CP22) and the first preliminary bonding pads 310a and may expose, instead of cover, the upper surfaces of the first preliminary bonding pads 310a.

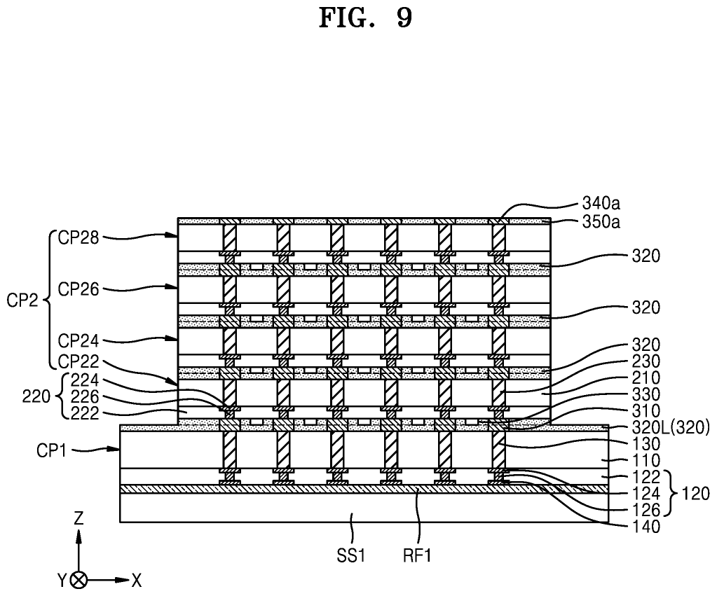

Referring to FIG. 9, the second semiconductor chips CP24, CP26, and CP28 may be sequentially located on the lowermost second semiconductor chip (e.g., the second semiconductor chip CP22) located on the first semiconductor chip CP1. The second preliminary bonding pads 310b and the second preliminary bonding insulating layer 320b may be formed on the lower surfaces of the second semiconductor chips CP24, CP26, and CP28, sequentially located on the lowermost second semiconductor chip (e.g., the second semiconductor chip CP22). The first preliminary bonding pads 310a and the first preliminary bonding insulating layer 320a may be formed on the upper surfaces of the second semiconductor chips CP24 and CP26, and not on the uppermost second semiconductor chip (e.g., the second semiconductor chip CP28). First preliminary support bonding pad 340a and a first preliminary support bonding insulating layer 350a may be formed on the upper surface of the uppermost second semiconductor chip (e.g., the second semiconductor chip CP28).

Similar to the above, the first void controllers 330 may be formed by removing local regions from the upper surface of the insulating film for forming the first preliminary bonding insulating layer 320a, the first void controllers 330 may be formed by removing local regions from the lower surface of the insulating film for forming the second preliminary bonding insulating layer 320b, or the first void controllers 330 may be formed by removing local regions from the upper surface of the insulating film for forming the first preliminary bonding insulating layer 320a and the lower surface of the insulating film for forming the second preliminary bonding insulating layer 320b.

Thereafter, the second semiconductor chips CP24, CP26 and CP28 may be sequentially aligned on the lowermost second semiconductor chip (e.g., the second semiconductor chip CP22) and sequentially bonded to each other so that the first preliminary bonding pads 310a may face the second preliminary bonding pads 310b. In some embodiments, the first preliminary bonding pads 310a may be bonded to the second preliminary bonding pads 310b and the first preliminary bonding insulating layer 320a may be bonded to the second preliminary bonding insulating layer 320b, by applying heat, pressure, or combinations thereof.

The first preliminary bonding pads 310a may be bonded to the second preliminary bonding pads 310b corresponding thereto to form the bonding pads 310. Similarly, the first preliminary bonding insulating layer 320a may be bonded to the second preliminary bonding insulating layer 320b to form the bonding insulating layer 320. As a result, the second semiconductor chips CP24, CP26, and CP28 may be sequentially bonded to the lowermost second semiconductor chip (e.g., the second semiconductor chip CP22) and each other without a separate adhesive layer.

As the second semiconductor chips CP24, CP26, and CP28 are sequentially bonded to the lowermost second semiconductor chip (e.g., the second semiconductor chip CP22 and each other), the first void controller 330 may be formed as a cavity filled with an inert gas or gaseous material. In some embodiments, the first void controllers 330 may be a cavity closed by (e.g., defined by) the bonding insulating layer 320, one of the second semiconductor chips CP2 and the bonding insulating layer 320, and the second semiconductor chips CP2 and the bonding insulating layer 320.

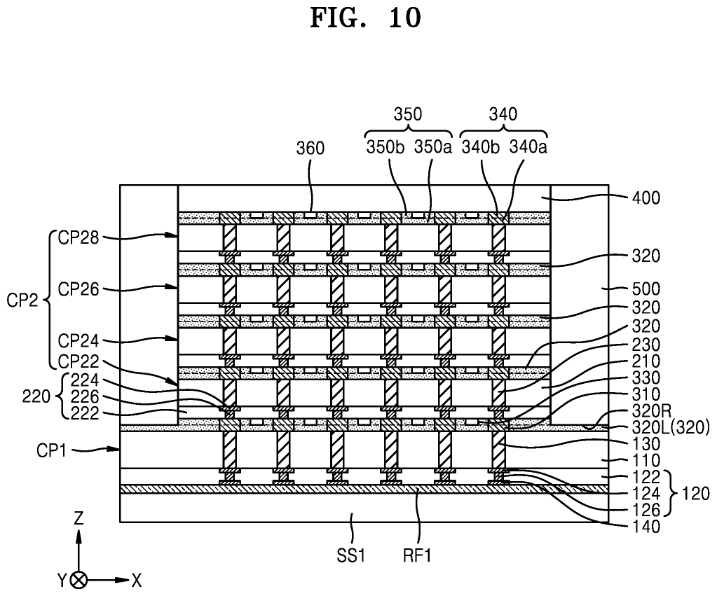

Referring to FIG. 10, after the second preliminary support bonding pads 340b and the second preliminary support bonding insulating layer 350b are formed on the lower surface of the dummy support substrate 400, the dummy support substrate 400 may be located on the uppermost second semiconductor chip (e.g., the second semiconductor chip CP28). The dummy support substrate 400 may be located on the uppermost second semiconductor chip (e.g., the second semiconductor chip CP28) by using the edge of the uppermost second semiconductor chip (e.g., the second semiconductor chip CP28) as an alignment key.

Similar to the process of forming the first void controllers 330, the second void controllers 360 may be formed by removing local regions from the upper surface of the insulating film for forming the first preliminary support bonding insulating layer 350a, the second void controllers 360 may be formed by removing local regions from the lower surface of the insulating film for forming the second preliminary support bonding insulating layer 350b, or the second void controllers 360 may be formed by removing local regions from the upper surface of the insulating film for forming the first preliminary support bonding insulating layer 350a and from the lower surface of the insulating film for forming the second preliminary support bonding insulating layer 350b.

Similar to the first void controllers 330, the uppermost second semiconductor chip (e.g., the second semiconductor chip CP28) or the dummy support substrate 400 may be exposed from the second void controllers 360. In another embodiment, the first preliminary support bonding insulating layer 350a may be exposed from the second void controllers 360 without exposing the uppermost second semiconductor chip (e.g., the second semiconductor chip CP28), and the second preliminary support bonding insulating layer 350b may be exposed without exposing the dummy support substrate 400.

Thereafter, similar to the above description, the dummy support substrate 400 may be aligned on the uppermost second semiconductor chip (e.g., the second semiconductor chip CP28) so that the first preliminary support bonding pads 340a faces the second preliminary support bonding pads 340b, and the dummy support substrate 400 may be bonded to the uppermost second semiconductor chip (e.g., the second semiconductor chip CP28). In some embodiments, the first preliminary support bonding pad 340a may be bonded to the second preliminary support bonding pads 340b and the first preliminary support bonding insulating layer 350a may be bonded to the second preliminary support bonding insulating layer 350b, by applying heat, pressure, or combinations thereof.

The support bonding pads 340 may be formed by bonding the first preliminary support bonding pads 340a to the second preliminary support bonding pads 340b. Similarly, the support bonding insulating layer 350 may be formed by bonding the first preliminary support bonding insulating layer 350a to the second preliminary support bonding insulating layer 350b. As a result, the dummy support substrate 400 may be directly bonded to the uppermost second semiconductor chip (e.g., the second semiconductor chip CP28) without a separate adhesive layer.

By bonding the dummy support substrate 400 to the uppermost second semiconductor chip (e.g., the second semiconductor chip CP28), the second void controllers 360 may be formed as a cavity filled with an inert gas or gaseous material. In some embodiments, the second void controllers 360 may be a cavity closed by (e.g., defined by) the support bonding insulating layer 350 and the uppermost second semiconductor chip (e.g., the second semiconductor chip CP28); the dummy support substrate 400, and the support bonding insulating layer 350; or the uppermost second semiconductor chip (e.g., the second semiconductor chip CP28), the dummy support substrate 400, and the support bonding insulating layer 350.

Thereafter, a package molding layer 500 covering the upper surface of the first semiconductor chip CP1 and surrounding the side surfaces of the second semiconductor chips CP2 and the dummy support substrate 400 may be formed on the first semiconductor chip CP1.

After the package molding layer 500 is formed, the first support substrate SS1 to which the first release film RF1 is attached may be separated from the first semiconductor chip CP1.

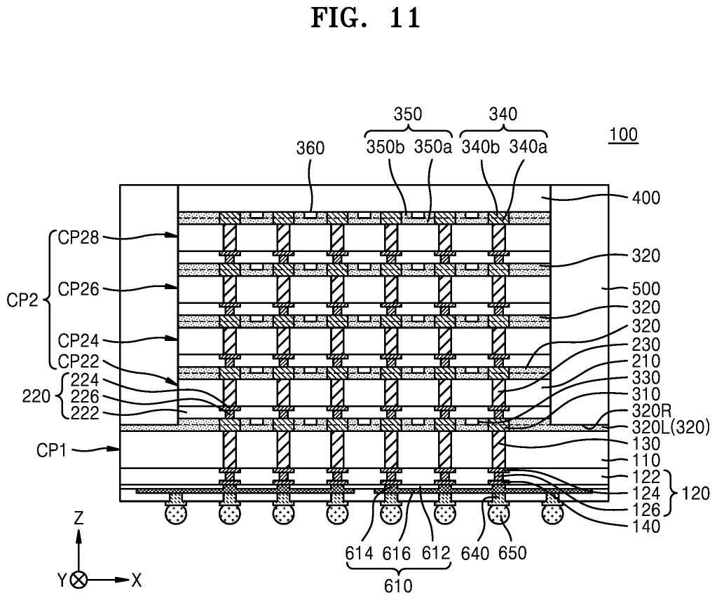

Referring to FIG. 11, in the result of FIG. 10, the base redistribution layer 610 may be formed on the first interconnection structure 120 of the first semiconductor chip CP1. The result of FIG. 10 may be reversed (e.g., flipped upside down) and attached to a second support substrate, to which a second release film is provided, to form the base redistribution layer 610. Depending on the process, the second release film may be omitted. Here, the second release film may be formed on the upper surface of the second support substrate, and the dummy support substrate 400 and the package molding layer 500 may be attached to an upper surface of the second release film.

The base redistribution layer 610 may include the package redistribution insulating layer 612, the package redistribution vias 614, and the package redistribution line patterns 616. At least some of the package redistribution vias 614 or at least some of the package redistribution line patterns 616 may be formed to contact the chip pads 140. Among the package redistribution line patterns 616, the package redistribution line patterns 616 disposed on or at the upper surface of the base redistribution layer 610 may form the package pads 640.

The package connection terminals 650 may be attached to the package pads 640, respectively. For example, each of the package connection terminals 650 may be a solder ball or a bump. Depending on the process, the base redistribution layer 610 may be omitted. In this case, the package connection terminals 650 may be attached to the chip pads 140.

While non-limiting example embodiments have been particularly shown and described with reference to the drawings, it will be understood that various changes in form and details may be made therein without departing from the spirit and scope of the present disclosure.

What is claimed is:

1. A semiconductor package comprising:
a plurality of semiconductor chips;
a plurality of bonding pads between two of the plurality of semiconductor chips;
a bonding insulating layer surrounding the plurality of bonding pads between the two of the plurality of semiconductor chips; and
a void controller between the plurality of bonding pads,
wherein the plurality of bonding pads are directly connected to the two of the plurality of semiconductor chips,
wherein the bonding insulating layer is directly connected to the two of the plurality of semiconductor chips,
wherein the void controller is a cavity defined by the bonding insulating layer, one of the plurality of semiconductor chips, and the bonding insulating layer, or the one of the plurality of semiconductor chips and the bonding insulating layer, and
wherein the void controller is filled with a gas.

2. The semiconductor package of claim 1, wherein a vertical length of the void controller is equal to or less than a vertical length of the bonding insulating layer.

3. The semiconductor package of claim 1, wherein the void controller is spaced apart from the plurality of bonding pads with a portion of the bonding insulating layer therebetween.

4. The semiconductor package of claim 1, wherein the void controller is defined by the one of the plurality of semiconductor chips and the bonding insulating layer.

5. The semiconductor package of claim 1, wherein the void controller is spaced apart from a first semiconductor chip among the two of the plurality of semiconductor chips with a first portion of the bonding insulating layer therebetween, and the void controller is spaced out from a second semiconductor chip among the two of the plurality of semiconductor chips with a second portion of the bonding insulating layer therebetween.

6. The semiconductor package of claim 1, wherein the void controller has a line shape extending in one direction.

7. The semiconductor package of claim 1, wherein the void controller has a cross shape.

8. The semiconductor package of claim 1, wherein the plurality of bonding pads are provided in at least one row, at least one column, or combinations thereof, and
wherein the void controller overlaps with the at least one row of the plurality of bonding pads in a first horizontal direction or overlaps with the at least one column of the plurality of bonding pads in a second horizontal direction that crosses the first horizontal direction.

9. The semiconductor package of claim 1, wherein one end of the void controller faces a chip edge of the plurality of semiconductor chips.

10. The semiconductor package of claim 1, wherein the void controller has a slit shape, a groove shape, or a recess shape.

11. A semiconductor package comprising:
a first semiconductor chip comprising:
a first semiconductor substrate comprising an active surface and an inactive surface opposite to each other; and
first through-electrodes passing through the first semiconductor substrate; and
second semiconductor chips, each comprising:
a second semiconductor substrate comprising an active surface and an inactive surface opposite to each other; and
second through-electrodes passing through the second semiconductor substrate,
wherein the second semiconductor chips are stacked on the first semiconductor chip so that the active surface of the second semiconductor substrate faces towards the inactive surface of the first semiconductor substrate,
wherein the semiconductor package further comprises:
first bonding pads between the first semiconductor chip and a lowermost second semiconductor chip among the second semiconductor chips, the first bonding pads electrically connecting the first through-electrodes and the second through-electrodes of the lowermost second semiconductor chip;
second bonding pads between a pair of the second semiconductor chips, among the second semiconductor chips, that are adjacent to each other, the second bonding pads electrically connecting the second through-electrodes of one second semiconductor chip among the pair of the second semiconductor chips to another second semiconductor chip among the pair of the second semiconductor chips;
a first bonding insulating layer surrounding the first bonding pads, and between the first semiconductor chip and the lowermost second semiconductor chip;
a second bonding insulating layer surrounding the second bonding pads; and between the pair of the second semiconductor chips, and
a first void controller between the first bonding pads or between the second bonding pads, and
wherein the first void controller comprises a cavity filled with a gas.

12. The semiconductor package of claim 11, wherein the cavity of the first void controller is defined by the first bonding insulating layer and the first semiconductor chip, or by the second bonding insulating layer and one of the second semiconductor chips.

13. The semiconductor package of claim 11, wherein the cavity of the first void controller is defined by the first bonding insulating layer, the first semiconductor chip, and the lowermost second semiconductor chip, or by the second bonding insulating layer and the pair of the second semiconductor chips.

14. The semiconductor package of claim 11, wherein the first void controller is defined by the first bonding insulating layer or the second bonding insulating layer.

15. The semiconductor package of claim 11, wherein the first void controller exposes a portion of an upper surface of the first semiconductor chip, exposes a portion of an upper surface of one of the second semiconductor chips, or exposes a portion of a lower surface of the one of the second semiconductor chips.

16. The semiconductor package of claim 11, further comprising:
a dummy support substrate on an uppermost second semiconductor chip among the second semiconductor chips;
support bonding pads between the uppermost second semiconductor chip and the dummy support substrate;
a support bonding insulating layer surrounding the support bonding pads and between the uppermost second semiconductor chip and the dummy support substrate; and
a second void controller between the support bonding pads,
wherein the second void controller comprises a cavity filled with a gas.

17. The semiconductor package of claim 11, wherein the first void controller has a slit shape, a groove shape, or a recess shape.

18. A semiconductor package comprising:
a first semiconductor chip comprising:
a first semiconductor substrate comprising an active surface and an inactive surface opposite to each other; and
first through-electrodes passing through the first semiconductor substrate; and
second semiconductor chips, each comprising:
a second semiconductor substrate comprising an active surface and an inactive surface opposite to each other; and
second through-electrodes passing through the second semiconductor substrate,
wherein the second semiconductor chips are stacked on the first semiconductor chip so that the active surface of the second semiconductor substrate faces towards the inactive surface of the first semiconductor substrate,
wherein the semiconductor package further comprises:
first bonding pads between the first semiconductor chip and a lowermost second semiconductor chip among the second semiconductor chips, the first bonding pads electrically connecting the first through-electrodes and the second through-electrodes of the lowermost second semiconductor chip;
second bonding pads between a pair of the second semiconductor chips, among the second semiconductor chips, that are adjacent to each other, the second bonding pads electrically connecting the second through-electrodes of one second semiconductor chip among the pair of the second semiconductor chips to another second semiconductor chip among the pair of the second semiconductor chips;
a first bonding insulating layer surrounding the first bonding pads, and between the first semiconductor chip and the lowermost second semiconductor chip;
a second bonding insulating layer surrounding the second bonding pads, and between the pair of the second semiconductor chips; and
a first void controller that is between and separated from the first bonding pads, and
wherein the first void controller comprises a cavity that is defined by at least one from among the first bonding insulating layer, the first semiconductor chip, and the lowermost second semiconductor chip.

19. The semiconductor package of claim 18, further comprising:
a dummy support substrate on an uppermost second semiconductor chip among the second semiconductor chips;
support bonding pads between the uppermost second semiconductor chip and the dummy support substrate;
a support bonding insulating layer surrounding the support bonding pads and between the uppermost second semiconductor chip and the dummy support substrate; and
a second void controller between and separated from the support bonding pads,
wherein the second void controller comprises a cavity that is defined by at least one from among the support bonding insulating layer, the uppermost second semiconductor chip, and the dummy support substrate.

20. The semiconductor package of claim 18, further comprising a package molding portion on an upper surface of the first semiconductor chip and on sidewalls of the second semiconductor chips.
